(19) United States
(12) Patent Application Publication
(10) Pub. No.: US 2002/0132188 A1
(43) Pub. Date: Sep. 19, 2002

(54) PLANOGRAPHIC PRINTING

(76) Inventors: KEVIN BARRY RAY, Morley (GB); CHRISTOPHER DAVID MCCULLOUGH, Sherburn-in-Elmet (GB); MARK JOHN SPOWAGE, Swillington (GB)

Correspondence Address: BAKER & BOTTS, 30 ROCKEFELLER PLAZA, NEW YORK, NY, 10112

(21) Appl. No.: 09/448,393

(22) Filed: Nov. 23, 1999

Related U.S. Application Data
(63) Continuation of application No. PCT/GB98/01484, filed on May 22, 1998.

(30) Foreign Application Priority Data
May 23, 1997 (GB) 9710551.4

(51) Int. Cl. G03F 7/00; B41N 1/00

(52) U.S. Cl. 430/302; 101/457; 101/450.1

(57) ABSTRACT

A method of preparing a printing member or a printing member precursor involves contacting a substrate with an aqueous formulation comprising a polyester having pendent hydrophilic groups wherein said polyester has optionally been combined with a second compound. Said pendent hydrophilic groups may be selected from alkvleiie oxide moieties, carboxyl groups, amino groups, sulphonic groups, phosphoric groups, sulphuric acid ester salts, hydroxyl groups, salts of any other aforesa-id and quaternary immonium salts in general. Said printing member is preferably a lithographic printing member. It may be for use in wet or dry printing.

This invention relates to planographic printing and provides a method of preparing a planographic printing member and a planographic printing member Per se. The invention particularly, although not exclusively, relates to lithographic printing.

Lithographic processes involve establishing image (printing) and non-image (non-printing) areas on a substrate, substantially on a common plane. When such processes are used in printing industries, non-image areas G-and image areas are arranged to have different affinities for printing ink. For example, non-image areas may be generally hydrophilic or oleophobic and image areas may be oleophilic. In “wet” lithographic printing, a dampening or fountain (water-based) liquid is applied initially to a plate prior to application of ink so that it adheres to the non-image-areas and.repels oil based inks therefrom. In “dry” printing, ink is repelled from non-image areas due to their release property.

There are numerous knowniprocesses for creating image and non-image areas. A conventional lithographic plate comprises a substrate coated with a photosensitive material which may comprise, for example, diazonium/diazide materials, polymers which undergo depolymerisation or addition polymerisation and silver halide gelatin assemblies. Exposed areas of conventional plates are either rendered more or less soluble in a developer formulation, so that upon development either positive or negative printing plates are formed.

Recently, much work has been directed towards processes which use laser imaging, in view of the ease with which lasers can be controlled digitally. For example, U.S. Pat. No. 5 339 737 (Presstek) describes lithographic printing plates suitable for imaging by means of laser devices that emit in the near-infrared region. One plate described includes a substrate having an oleophilic layer, an ablatable layer over the oleophilic layer and a top hydrophilic layer. Imagewise laser exposure ablates areas of the ablatable layer which areas (together with the portions of the hydrophilic layer fixed thereto) are removed.

A plate for use in wet lithographic printing which is described in U.S. Pat. No. 5 339 737 has a hydrophilic layer derived from polyvinyl alcohol which is a water-soluble polymer. As a result, the hydrophilic layer gradually dissolves into the water-based dampening or fountain solution, thereby leading to a gradual acceptance of ink by non-image areas. Consequently, the number of prints obtainable from such a plate is severely limited.

WO94/18005 (Agfa) describes a substrate coated with an ink receptive layer over which an ablatable layer is provided. A hardened hydrophilic layer comprising titania, polyvinyl alcohol, tetramethylorthosilicate and a wetting agent is provided over the ablatable layer. Disadvantageously, the hydrophilic layer needs to be hardened at an elevated temperature for a period of at least several hours and for some cases up to a week (see U.S. Pat. No. 5 462 833) in order to provide a viable product.

Another process for creating image and non-image areas involves the use of a Direct Phase Change (DPC) system which refers to an imageable layer wherein ink-accepting and non-ink-accepting, for example hydrophilic and oleophilic, areas are created by the exposure process alone—that is, without development or further processing. In such systems, exposed areas of an image layer are transformed into the other one of a non-ink-accepting or ink-accepting material.

It will be appreciated from the above that a common feature of many types of lithographic processes is the provision of a hydrophilic layer and numerous different types of hydrophilic layers have been proposed.

One object of the present invention is to address the problem of providing a hydrophilic layer on a printing member.

According to a first aspect of the invention, there is providedla method of preparing a printing member or a printing member precursor, the method comprising contacting a substrate with an aqueous formulation comprising a polyester having pendent hydrophilic groups, wherein said polyester has optionally been combined with a second compound.

Said formulation and/or said polyester is/are preferably arranged to define a hydrophilic layer. Said layer may have a dry film weight of at least 1 gmr, preferably at least 2 gm2, more preferably at least 3 gm2, especially at least 4 gm². Said dry film weight may be less than 20 gm2, suitably less than 10 gm−2, preferably less than 8 gm−2, more preferably less than 7 gm−2, especially 6 gm2 or less.

Said formulation may be dried after contact with said substrate. However, it has been noted that the hydrophilicity may be reduced upon prolonged drying. Preferably, said formulation is dried at an elevated temperature, suitably of at least 50° C., preferably 75° C., more preferably 100° C. for less than 30 minutes, preferably less than 20 minutes, more preferably less than 10 minutes, especially less than 5 minutes. Preferably, the temperature of said drying does not exceed 300° C., more preferably does not exceed 250° C., especially does not excess 200° C.

The hydrophilicity of said polyester when defining a layer on a substrate (and suitably in the absence of any other additives) may be assessed by determining the advancing contact angle of the layer in water, for example by using a Cahn Dynamic Contact Angle Analyser. Said contact angle may be less than 40 degrees, suitably less than 30 degrees, preferably less than 20 degrees, more preferably less than 15 degrees, especially less than 10 degrees.

Said hydrophilic groups may be selected from alkylene oxide moieties, carboxyl groups, amino groups, sulphonic groups, phosphoric groups, sulphuric acid ester salts, hydroxyl groups, salts of any other aforesaid and quaternary ammonium salts in general.

The cations of said salts may be selected from alkali metal cations, especially of sodium and potassium, and from cations of general formula N⁺R¹R²R³R⁴ wherein RI, R², R³ and R⁴ are each independently selected from a hydrogen atom and an optionally-substituted, preferably an unsubstituted, alkyl group. R¹, R², R³ and R⁴ may be the same or different, but are preferably the same. Where R¹, R², R³ and/or R⁴ represent an alkyl group, they suitably represent a C₁₋₄, preferably a C_{1-2,} especially a methyl, group.

Preferred alkylene oxide moieties are ethylene oxide moieties.

Sulphonic groups may be of general formula -SO₃X wherein X represents a hydrogen atom or a cationic atom or group. For example, when X represents a cationic atom or group, it may represent an alkali metal cation, especially of sodium or potassium or a cation of general formula N⁺R¹R²R³R⁴ as described above. Preferably, x represents a hydrogen atom, a sodium or potassium cation or an ammonium or tetraalkyl, especially a tetramethyl, ammonium cation.

Phosphoric groups may be phosphoric acid ester salts.

Preferably, said polyester has pendent sulphonic groups. Preferred groups include sulphonate amine salts, ammonium sulphonates and alkali metal sulphonates.

Said polyester may include more than one type of pendent hydrophilic group. Preferably, however, said polyester includes only one type of such groups.

The ratio of the number of moles of pendent hydrophilic groups to ester linkages in said polyester may be at least 0.05, suitably at least 0.06, preferably at least 0.07, more preferably at least 0.075, especially at least 0.08. Said ratio may be less than 0.5, suitably less than 0.3, preferably less than 0.15, especially less than 0.11. It is found that the aforementioned ratio can be adjusted to-vary the properties of the polyester. For example, when the ratio is relatively high, for example 0.11 or greater the polyester is readily dispersed in water. When the ratio is too low the water dispersibility may be low. Additionally, when the ratio is too high, the water resistance of a hydrophilic layer prepared from the formulation may be poor. An especially advantageous range for said ratio is 0.075 to 0.109.

Advantageously, when using a polyester of the type described, the amount of organic solvent included in the formulation can be minimized. Said formulation contacted with said substrate in the method may include less than 50 wt%, suitably less than 30 wt%, preferably less than 10 wt%, more preferably less than 1 wt%, especially essentially 0 wt% of organic solvent.

Said polyester may be a resin which is suitably amorphous and may have a molecular weight of at least 100, suitably at least 250, preferably at least 500, more preferably at least 1000, especially at least 2000. The molecular weight may be less than 50,000, preferably less than 30,000, more preferably less than 20,000, especially less than 10,000.

Said polyester may incorporate a polyalkylene ether, especially a polyethylene ether, chain. Said polyester may incorporate an alkylene glycol moiety. Such a moiety may be linear or branched and may have up to 6 carbon atoms. Preferred alkylene glycol moieties include ethylene glycol and neopentyl glycol moieties.

Said polyester may include a first repeat unit which may be aliphatic, aromatic or alicyclic. An aliphatic repeat unit may be an optionally substituted, especially an unsubstituted, alkylene moiety. Such a moiety may have up to 40 carbon atoms, preferably up to 10, more preferably up to 8, especially up to 6, carbon atoms. Specific examples include -(CH₂)₈- and -(CH₂)₄-. An aromatic repeat unit may be an optionally-substituted, especially an unsubstituted, phenylene or naphthylene moiety. Of these, a phenylene unit is preferred. An alicyclic repeat unit may be an optionally-substituted, especially an unsubstituted, cyclohexylene moiety.

Preferably, said first repeat unit is an aromatic repeat unit, with phenylene being especially preferred.

Preferably, said polyester includes a repeat unit of formula

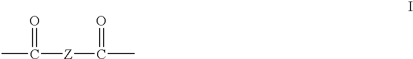

wherein Z represents said first repeat unit described., Preferably, said repeat unit of formula I is derived from a carboxylic acid or carboxylic acid derivative providing at least two -COO- groups. said polyester may include one or more different first repeat units of the type described. For example, in one embodiment, said first repeat unit may comprise at least two isomeric (di-COO-)phenyl moieties, which may be derived from terephthalic acid and isophthalic acid.

Said polyester may include a second repea t unit which may be aliphatic, aromatic or alicyclic. It is pref erably aliphatic or alicyclic, especially aliphatic. Aliphatic units may, have up to ten carbon atoms. They may incorporate ether oxygen atoms, as in, for example, a moiety ofv formula -(CH₂)₂O (CH₂)₂- or a polyethylene oxide moiety. Preferred aliphatic groups are alkylene moieties. Alicyclic groups may include a cyclohexylene moiety.

Preferably, said polyester includes a repeat unit of formula.

-O-Y-O- II

wherein Y represents said second repeat unit described. Preferably, said repeat unit of formula II is derived or derivable from a compound having at least two hydroxy groups.

Said polyester may include one or more different second repeat units of the type described. For example, in one embodiment, said repeat units may be derived from ethylene glycol and neopentyl glycol.

Said polyester preferably includes a third repeat unit which includes a said pendent hydrophilic group. Said third unit may comprise a said first unit described above when substituted so as to provide a said pendent hydrophilic group as described above. Suitable third repeat units include an aromatic repeat unit, with phenylene being preferred and (di-COO-)phenyl being especially preferred. Said polyester may include one or more, preferably only one, type of third repeat unit.

Said polyesters of the first aspect are not limited to those only comprising the abovementioned first, second and third repeat units described and substances which can be incorporated include unsaturated aliphatic or unsaturated alicyclic polybasic acids such as maleic acid, fumaric acid and itaconic acid, or hydroxycarboxylic acids such as p-hydroxybenzoic acid and p-(β-hydroxyethoxy) benzoic acid. Where the aforementioned are incorporated, they may be incorporated at a relatively low level, for example such that the ratio of the number of ester linkage to the number of molecules of said components is at least 9 and is preferably at least 15.

Said polyester is preferably linear. Said polyester is preferably saturated. Said polyester is preferably a copolymer.

Said formulation preferably has a pH of greater than 2, more preferably greater than 4, especially greater than 6. The pH may be less than 12, preferably less than 10, more preferably less than 8, especially less than 7.

Said aqueous formulation may include at least 1 wt%, suitably at least 10 wt%, preferably at least 15 wt% more preferably at least 20 wt% of said polyester. Said formulation may include less than 70 wt%, preferably less than 60 wt%, more preferably less than 50 wt%, especially less than 40 wt% of said polyester.

Said polyester may be prepared by reacting: one or more first polybasic acid component or a derivative, for example an ester type derivative thereof (which is suitably arranged to provide said first repeat unit described above); one or more polyol component or a derivative, for example an ester derivative thereof (which suitably is arranged to provide said second repeat unit described above); and a second polybasic acid component or a derivative, for example an ester type derivative thereof, suitably having a said pendent hydrophilic group (which is suitably arranged to provide said third repeat unit described above).

Examples of first polybasic acids include terephthalic, acid, isophthalic acid, phthalic acid, phthalic anhydride, 2,6-naphthalenedicarboxylic acid, 1,4-cyclohexanonedicarboxylic acid, adipic acid, sebacic acid, trimellitic acid, pyromellitic acid, dimer acid, and the like, and one or more of these may be used.

There are no absolute limitations on the polyol components, and it can be aliphatic, aromatic or alicyclic, and specific examples include ethylene glycol, diethylene glycol, 1,4-butanediol, neopentyl glycol, dipropylene glycol, 1,6-hexanediol, 1,4-cyclohexane-dimethanol, -xylylene glycol, -dimethylolpropionic acid, glycerin,.trimethylolpropane, poly(ethylene oxide) glycol and poly(tetramethylene oxide) glycol.

Said second polybasic acid component is preferably a dicarboxylic acid (or derivative thereof) which is arranged to introduce said hydrophilic groups into said polyester. Examples include alicyclic, aliphatic or aromatic dicarboxylic acids which contain substitutents such as sulphonate amine salts, ammonium sulphonates and alkali metal sulphonates, for example, sodium 5-sulphoisophthalic acid, ammonium 5-sulphoisopthalic acid, sodium 4-sulphoisophthalic acid, methylammonium-4-sulphoisophthalic acid, sodium 2-sulphoterephthalic acid, potassium 5-sulphoisophthalic acid, potassium 4-sulphoisophthalic acid,. potassium 2-sulphoterephthalic acid and sodium sulphosuccinic acid.

In the method, the ratio of the total number of moles of said one or more first polybasic acid component (or derivatives thereof) to the total number of moles of said one or more polyol component (or derivatives thereof) may be in the range of 0.5 to 1.5, preferably in the range 0.6 to 1.0, more preferably in the range 0.7 to 1.0, especially in the range 0.8 to 1.0. The ratio of the total number of moles of said second polybasic acid component (or the derivatives thereof) to the total number of moles of said one or more first polybasic acid component (or the derivatives thereof) may be in the range 0.05 to 0.17, preferably in the range 0.07 to 0.15, more preferably in the range 0.09 to 0.13, especially in the range 0.1 to 0.12. The ratio of the total number of moles of said second polybasic acid component (or the derivatives thereof) to the total number of moles of said one or more polyol component (or the derivatives thereof) may be in the range 0.06 to 0.16, preferably in the range 0.09 to 0.14, more preferably in the range 0.09 to 0.12 especially in the range 0.09 to 0.11.

The polyester described may be prepared by any suitable reaction and many such reactions are well-known to skilled persons in the art, f or example as described in Chapter 12 of Polymer Chemistry—an Introduction, Malcolm P. Stevens., 2nd Edition,, Oxford Student Edition, 1990. Preferably, said polyester is made by a polycondensation reaction. The polyester resin prepared may then be added to water at 70 to 80° C. at a resin concentration of from 1 to 70 wt%, preferably from 20 to 40 wt%, and this may be agitated and heated for 2 to 5 hours. The resulting polyester resin is uniformly dissolved and dispersed in the warm water and this homnogenous dispersion remains stable even when cooled to ambient temperature. Advantageously, said dispersion may remain stable in the absence of any emulsifiers. The ratio of the amount of polyester resin to the amount of water is preferably from 1 to 70/99 to 30 because if there is too little polyester resin, the viscosity is too low and there may be poor adhesion to said substrate, whereas if there is too much polyester resin, the viscosity is too great which reduces-workability.

It should be noted that when the abovementioned dispersion is prepared, various additives can be included, depending on the intended use of the dispersion. For example,,30 parts by weight or less, preferably 10 parts by weight or less, of plasticizer can be added per 100 parts by weight of polyester resin. Other examples include static charge preventers, blocking preventers (wax, polyethylene emulsions and the like) and fillers (calcium carbonate, clay, silica and the like). Furthermore, it is also possible, if necessary, to admix other water soluble resins, for example, urethane resins, acrylic resins, epoxy resins, melamine resins and the like.

Specific examples of components used to prepare formulations A to D by polycondensation reactions are shown in the table below.

| Component | A (mol %) | B (mol %) | C (mol %) | D (mol %) |
|---|---|---|---|---|
| Terephthalic | 45 | 46 | 44 | 46 |
| acid | | | | |
| Isophthalic | 45 | 46 | 45 | 47 |
| acid | | | | |
| Sodium 5- | 10 | 8 | 11 | 7 |
| sulfo- | | | | |
| isophthalic | | | | |
| acid | | | | |
| Ethylene | 40 | 40 | 40 | 40 |
| glycol | | | | |
| Neopentyl | 60 | 60 | 60 | 60 |
| glycol | | | | |

30, parts by weight of the respective polyester resins A to D were then added to 70 parts by weight of water at 70 to 80° C. and agitated for 4 hours whilst maintaining the temperature at 70° C. The formulations were then cooled to yield polyester resin dispersions having a solids content of 30% by weight. The pH values of the dispersions were 6.5, 6.6, 6.6, 6.5 for formulations including respective resins A to D.

In the method of the first aspect, said aqueous formulation preferably comprises a said dispersion of said polyester resin in water.

Said formulation described may include a silicate material, preferably in the form of a silicate solution.

Said silicate solution may comprise a solution of any soluble silicate including compounds often referred to as water glasses, metasilicates, orthosilicates and sesquisilicates. Said silicate solution may comprise a solution of a modified silicate for example a borosilicate or phosphosilicate.

Said silicate solution may comprise one or more, preferably only one, metal or non-metal silicate. A metal silicate may be- an alkali metal silicate. A non-metal silicate may be quaternary ammonium silicate.

Said silicate solution may be formed from silicate wherein the ratio of the number of moles of Si species, for example SiO₂, to the number of moles of cationic, for example metal species is in the range 0.25 to 10, preferably in the range 0.25 to about 6, more preferably in the range 0.5 to 4.

Said silicate is preferably alkali metal silicate. In this case, the ratio of the number of moles of SiO₂ to the number of moles of M₂O in said silicate, where M represents an alkali metal may be at least 0.25, suitably at least 0.5, preferably at least 1, more preferably at least 1.5. Especially preferred is the case wherein said ratio is at least 2.5. Said ratio may be less than 6, preferably less than 5 and more preferably less than 4.

Preferred alkali metal silicates include lithium, sodium and potassium silicates, with lithium and/or sodium silicate being especially preferred. A silicate solution comprising only sodium silicate is most preferred.

Said formulation may include particulate material.

Said formulation may include 5 to 60 wt% of particulate material. Preferably, the fluid includes 10 to 50 wt%, more preferably 15 to 45 wt%, especially 20 to 40 wt% of particulate material.

Said particulate material may be an organic or an inorganic material. Organic particulate materials may be provided by latexes. Inorganic particulate materials may be selected from alumina, silica, silicon carbide, zinc sulphide, zirconia, barium sulphate, talcs, clays (e.g. kaolin), lithopone and titanium oxide.

Said particulate material may comprise a first material which may have a hardness of greater than 8 Modified Mohs (on a scale of 0 to 15), preferably greater than 9 and, more preferably, greater than 10 Modified Mohs.

Said first material may have a mean particle size of at least 0.1 μm and preferably at least 0.5 μm. Said first material may have a mean particle size of less than 45 μm, preferably less than 20 μm, more preferably less than 10 μm. The particle size distribution for 95% of particles of the first material may be in the range 0.01 to 150 μm, preferably in the range 0.05 to 75 μm, more preferably in the range 0.05 to 30 μm. Said first material preferably comprises an inorganic material. Said first material preferably comprises alumina which term includes Al₂O₃ and hydrates thereof, for example Al₂O₃.3H₂O. Preferably, said material is Al₂O₃.

Said particulate material in said formulation may include at least 20 wt%, preferably at least 30 wt% and, more preferably, at least 40 wt% of said first material. Said formulation may include 5 to 40 wt%, preferably 5 to 30 wt%, more preferably 7 to 25 wt%, especially 10 to 20 wt% of said first material.

Said particulate material may comprise a second material. Said second material may have a mean particle size of at least 0.001 μm, preferably at least 0.01 μm. Said second material may have a mean particle size of less than 10 μm, preferably less than 5 μm and, more preferably, less than 1 μm.

Mean particle sizes of said first and second materials suitably refer to the primary particle sizes of said materials.

Said, particulate material in said formulation may include at least 20 wt%, preferably at least 30 wt% and, more preferably, at least 40 wt% of said second material. Said formulation may include 5 to 40 wt%, preferably 5 to 30 wt%, more preferably 7 to 25 wt%, especially 10 to 20 wt% of said second material.

Said second material is preferably a pigment. Said second material is preferably inorganic. Said second material is preferably titanium dioxide.

Said first and second materials preferably define a multimodal, for example a bimodal particle size distribution.

Said substrate may include a support. Said support may include a metal surface. Preferred metals include aluminium, steel, tin or alloys of any of the aforesaid. Said metal surface may be provided over another material, for example over plastics or paper or said support may consist essentially of a metal or metals as aforesaid. Alternatively, said support may not include a metal surface as described, but may include a plastics surface. Said support may consist essentially of a plastics material (especially a polyester) or such a plastics material (especially a polyalkylene material such as polyethylene) may be provided as a coating over another support material, for example paper. In a further alternative, said support may consist essentially of paper or the like.

Said substrate may include an oleophilic surface, suitably provided by an oleophilic layer, which may comprise a resin for example a phenolic resin. Said oleophilic surface is preferably over said support. Preferably, said support and oleophilic layer are abutting.

Said substrate may include an ablatable layer which is suitably arranged to ablate on application of radiation, for example by means of a laser, preferably arranged to emit in the infrared region and, more preferably, arranged to emit in the near-IR region, suitably between 700 and 1500 nm. Said ablatable layer may include a first binder and a material capable of converting radiation into heat or may consist essentially of a homogenous material which is inherently adapted to be ablated.

Preferred first binders are polymeric, especially organic polymers, and include vinylchloride/vinylacetate copolymers, nitrocellulose and polyurethanes.

Preferred materials for converting radiation into heat include particulate materials such as carbon black and other pigments, metals, dyes and mixtures of the aforesaid.

Where a printing member precursor (ie. a product which needs further processing to enable it to be used as a printing plate) is prepared in the method, said method may include a further step of providing one or more further layers over the printing member precursor, suitably in order to prepare a printing member. One of said layers may comprise- an image layer which term includes a layer that can subsequently be partially removed in order to define areas to be printed. and includes a layer which already defines areas to be printed.

Said image layer may comprise any known photosensitive material whether arranged to form a positive or negative plate. Examples of photosensitive materials include diazonium/diazide materials, polymers which undergo depolymerisation or addition photopolymerisation and silver halide gelatin assemblies. Examples of suitable materials are disclosed in GB 1 592 281, GB 2 031 442, GB 2 069 164, GB 2 080 964, GB 2 109 573, EP 0 377 589, US 4 268 609 and U.S. Pat. No. 4 567 131.

Alternatively, said image layer in the form of a desired image for use in planographic printing may be deposited over said hydrophilic layer by a deposition process such as ink jet or laser ablation transfer. An example of the latter is described in US 5 171 650.

Said image layer may comprise a said ablatable layer as described herein.

One layer provided over the printing member precursor may comprise a said oleophilic layer as described herein.

Pref erably, a printing member prepared in a method described herein is arranged such that after exposure and optional development, at least part of an uppermost surface of the member comprises a hydrophilic layer formed by application of said formulation.

Where said polyester has been combined with a second compound, the combination preferably includes a product of a chemical reaction between said second compound and said polyester. Said second compound preferably comprises a resin which suitably includes functional groups capable of reacting with said polyester. Said second compound preferably includes glycidyl groups which suitably can be reacted with melamines and/or isocyanates. Preferably, said polyester is not reacted and/or combined with a said second compound prior to contact of said formulation with said substrate.

Said polyester may be cross-linked before or preferably after initial contact with said substrate. Any suitable cross-linking means may be used and such means is preferably a resin with melamine and/or isocyanate resins being preferred and melamine resins being especially preferred.

In a first preferred embodiment, said substrate contacted in said method may comprise a said support, a said oleophilic layer over said support and an ablatable layer over said oleophilic layer. Said formulation is preferably applied over said ablatable layer to prepare a negative ablatable printing plate.

In a second preferred embodiment, said substrate contacted in said method may comprise a said support and said formulation is suitably applied over said support to prepare a printing plate precursor over which an image layer may be provided. Said image layer may comprise an ablatable layer. An oleophilic layer may be provided over said ablatable layer.

In a third preferred embodiment, said substrate contacted in said method may comprise a said support and said formulation including particulate material as described. Preferably, said aqueous dispersion has been combined with said second compound in the embodiment. Any type of image layer may then be applied over said substrate.

In a fourth preferred embodiment, said, substrate cqontacted in said method may comprise a said support and an ablatable layer, suitably in the form of a metal layer, over said support, said formulation suitably being applied over said ablatable layer.

In a fifth preferred embodiment, said substrate contacted in said method may comprise a said support, with said formulation being applied over said support. A radiation-sensitive layer adapted so that non-exposed areas may be removed by applications of a force in a substantially dry process may be applied over said substrate, as described in Applicant's co-pending application number GB 9702953.2, the whole contents of which are incorporated herein by reference.

The radiation-sensitive layer of a plate (hereinafter a “rubber member”) prepared as described according to said fifth embodiment may be applied across substantially the entire printing surface of said printing member. Said force is preferably applied by moving a force applying means which is in contact with said printing member, suitably in direct contact with said radiation sensitive layer thereof, relative to said printing member. Said force applying means may be moved over the printing member. It may be moved back and forth as in a rubbing action. Alternatively and/or additionally, said force applying means may be moved away from the printing member.

Said force applying means may comprise a member which is brought into contact with said printing member in order to effect removal of said non-exposed areas or may comprise a member which is already in contact. For example, the latter described arrangement may comprise a cover means, such as a cover sheet in contact with the printing member and arranged to be removed by peeling thereby to remove said non-exposed areas. In this case, the adhesive force between the cover means and areas of the radiation sensitive layer before their exposure as compared to the force between the cover means and said areas after their exposure is substantially the same.

Said force applying means is preferably arranged to remove said non-exposed areas non-chemically. Preferably, said force applying means is arranged to physically overcome an adhesive force retaining said non-exposed areas in position.

Said force is preferably applied substantially in the absence of any liquid.

Preferably, a radiation sensitive layer of said rubber member is arranged to be less susceptible to removal after exposure by application of said force compared to its susceptibility before exposure.

Preferably, said radiation sensitive layer exhibits different physical properties after exposure compared to before exposure. Preferably, the difference in physical properties enables said non-exposed areas to be removed in preference to said exposed areas. For example, said radiation sensitive layer may become less plastic and/or sticky after exposure. The tensile strength of the radiation sensitive layer may increase after exposure. The elasticity of the radiation sensitive layer may be greater after exposure. The hardness of the radiation sensitive layer may be greater after exposure.

Preferably, said radiation sensitive layer is chemically different after exposure compared to before exposure.

Said radiation sensitive layer preferably incorporates a material (hereinafter “said reactive material”) adapted to have different physical properties after exposure compared to before exposure. Said reactive material is preferably a major component of said radiation sensitive layer. Said reactive material preferably has a glass transition temperature below 25° C. Preferably, said material is arranged to become less plastic and/or sticky after exposure. Preferably, the tensile strength of said material increases after exposure. Preferably, the elasticity of said material is greater after exposure than before exposure.

Preferably, said reactive material is arranged to be cross-linked upon exposure. More preferably, said reactive material is arranged to be vulcanized upon exposure.

Preferably, said reactive material comprises a rubber which may be natural, for example cis-polyisoprene or synthetic, for example being based on synthetic isoprene polymers, butyl rubbers, ethene-propene copolymers, vinyl polymers, styrene-butadiene, butadiene polymers or neoprene or the like.

Said rubber is preferably substantially water insoluble. It is preferably substantially soluble in organic solvents, for example cyclohexane.

Said reactive material may include more than one type of rubber, suitably blended together. For example, one rubber may be selected for its ability to be-removed in the method and another may be selected for its ability to be imaged. An example of such an arrangement is a blend comprising styrene-butadiene copolymers having different amounts of styrene.

Said radiation sensitive layer may include a radiation absorbing means, which is preferably arranged to convert light into heat. It may comprise a black body. Carbon black is preferred.

Said radiation sensitive layer may include a curing means which is arranged to aid curing of said reactive material on exposure.

Said radiation sensitive layer may include adhesion means for adjusting its adhesion to an underlying layer.

In a sixth preferred embodiment, said formulation may be arranged itself to define an image layer, for example when dry. In this event, such an image layer (referred to as a “direct phase change” image layer) may be transformed on image-wise exposure to radiation from being non-ink-accepting to being ink-accepting. Preferably, a radiation absorber is provided in said image layer suitably for converting radiation into heat. Said radiation absorber may be particulate, for example carbon black or another pigment; or it may be a dye; or mixtures of the aforesaid.

Said polyester of said sixth embodiment may be combined with a said second compound as aforesaid.

In a seventh preferred embodiment, said substrate contacted in said method may comprise a said support with said formulation being contacted with said support to provide a hydrophilic layer. An image layer may then be applied over said hydrophilic layer.

In an eighth preferred embodiment, said formulation may be applied over a substrate prepared as described according to said seventh embodiment or over a substrate comprising another type of hydrophilic layer, for example as described in Applicant's co-pending PCT Application No. PCT/GB96/02883.

In a ninth preferred embodiment said formulation may include a silicate and particulate material as described. At least 10 wt%, suitably at least 30 wt%, preferably at least 50 wt%, more preferably at least 65 wt%, especially at least 80 wt%, of said formulation is made up of said aqueous dispersion. The ratio of the weight of silicate to the weight of particulate material in the fluid is preferably in the range 0.1 to 2 and, more preferably, in the range 0.1 to 1. Especially preferred is the case wherein the ratio is in the range 0.2 to 0.6. The formulation according to the ninth embodiment may advantageously be applied to a plastics surface in order to provide a hydrophilic layer on said surface.

The invention extends to a method of preparing a printing member or printing member precursor, the method comprising contacting a substrate with an aqueous formulation comprising a polymeric compound having pendent hydrophilic groups, wherein said polymeric compound has optionally been combined with a second compound.

The polymeric compound referred to in the preceding paragraph may have any feature of the polyester of the first aspect (unless the context otherwise requires) and, accordingly, features of the polyester of the first aspect may apply to said polymeric material as if the term “polyester” is replaced with the term “polymeric compound”.

According to a second aspect of the present invention, there is provided a printing member or printing member precursor comprising a substrate provided with a first hydrophilic layer prepared or preparable by removing water from an aqueous formulation comprising a polyester having pendent hydrophilic groups, wherein said polyester has optionally been combined with a second compound.

According to a third aspect, there is provided a printing member or printing member precursor comprising a Insubstrate provided with a first hydrophilic layer which includes a polyester having pendent hydrophilic groups.

According to a fourth aspect of the present invention, there is provided a printing member or printing member precursor comprising a substrate provided with a first hydrophilic layer comprising a polyester having pendent hydrophilic groups wherein said polyester has optionally been combined with a second compound and said second compound has optionally been combined with other components of said layer.

The invention extends to a method of preparing a printing member, which comprises exposing a printing member precursor as described herein to imaging radiation.

Any feature of any aspect of any invention or embodiment described herein may be combined with any feature of any other aspect of any invention or embodiment described herein.

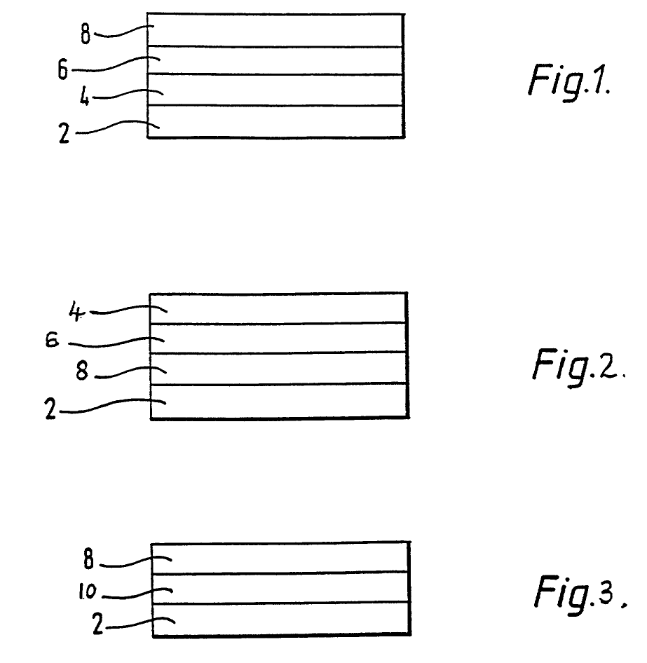

The invention will now be described, by way of example, with reference to FIGS. 1 to 3 which are schematic cross-sections through various lithographic plates. The following product are referred to hereinafter. BKR2620 (Trade Mark) Bakelite phenolic resin—refers to a phenol-formaldehyde-cresol resin of formula (C₇H₈O. C₆H,5. CH₂O), obtained from Georgia-Pacific Resins Inc. Decatur, Georgia, USA.

Dowanol PM—1-methoxy-propan-2-ol supplied by Chemitrade Limited of London, England.

Dispercel Tint Black STB-E (Trade Mark)—a carbon black/plasticised nitrocellulose dispersion obtained from Runnymede Dispersions Limited of Gloucestershire, England.

Nitrocellulose DHX 30/50 (Trade Mark)—high nitrogen grade (11.7-12.2%) nitrocellulose in chip form, obtained from ICI Explosives of Ayrshire, Scotland. PES 613D—a saturated polyester copolymer dispersion (20 wt% in water) obtained from Siber Hegner Limited of Kent, England

WAC-10 and WAC-20—modified copolyester resin dispersions (20 wt% in water) obtained from Siber Hegner Limited of Kent, England.

Si69 —bis(triethoxysilylpropyl)tetra sulphane—a silylether bonding agent for rubber obtained from Degussa of Macclesfield, England.

ST84 dye—SDA 1185—an indo-cyanine green dye supplied by H W Sands Corporation, Florida, USA. Bayhydur TP LS 2032—a hydrophilic aliphatic polyisocyanate obtained from Whitchem Limited of Staffordshire, England.

SMA 17352—a styrene/maleic anhydride half ester copolymer obtained from Elf Atochem U.K. Limited of Berkshire, England.

Beetle Resin BE3717—a part methylated melamine formaldehyde resin obtained from BIP Speciality Resins Limited of West Midlands, England.

Creo Trendsetter 3244—a high speed PostScript-compatible computer to plate imaging device using a thermal imaging head obtained from Creo Products Inc, of Canada.

Melinex 0—a polyethylene terephthlate film obtained from ICI.

Hombitan LW—Anatase titanium dioxide having a mean particle size of 0.2μm obtained from Sachtleben Chemie GmbH of Duisburg, Germany.

Alumina C₃—aluminium oxide having a mean particle size of 3μm obtained from Abralap of Surrey, England. LB 6564—a phenol-novolak resin obtained from Bakelite Resins of England.

Carbon black FW2—channel type carbon black obtained from Degussa of Macclesfield, England. Microlith Black C-K (Trade Mark)—refers to carbon black predispersed in vinyl chloride/vinyl acetate copolymer obtained from Ciba Pigments of Macclesfield, England.

Finaprene 411—a styrene butadiene copolymer with 31.6 wt% bound styrene (100% solids), obtained from Fina Chemicals of Surrey, England.

Finaprene 1205—a styrene butadiene copolymer with 23 wt% bound styrene (100% solids), obtained from Fina Chemicals of Surrey, England.

Robac TMTD PM (Trade Mark)—pellets of tetramethylthiuram disulphide (75 wt%) in a polymeric binding system based on ethylene propylene rubber—a vulcanisation accelerator, obtained from Robinson Brothers Ltd. of West Bromwich, England.

SBP 3 hydrocarbon—a hydrocarbon solvent obtained from Carless of Staffordshire, England.

Monazoline C—cocyl imidazoline obtained from Mona Industries Inc, New Jersey, USA.

KF654B PINA—as supplied by Riedel de Haan UK, Middlesex, UK believed to have the structure:

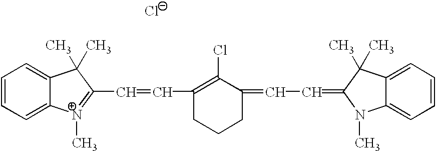

In the figures, the same or similar parts are annotated with the same reference numerals.

Unless otherwise stated, layers are applied using appropriate Meyer bars.

### EXAMPLE 1

Preparation of negative working ablatable printing plate A lithographic, printing plate was prepared having the construction shown in FIG. 1 wherein reference numeral 2 represents a support, 4 represents an oleophilic layer, 6 represents an ablatable layer and 8 represents a hydrophilic layer.

### Step 1 : Preparation of support

A 0.3 mm gauge aluminium alloy sheet of designation AA1050 was cut to a size of 230 mm by 350 mm, with the grain running lengthways. The sheet was then immersed face up in a solution of sodium hydroxide dissolved in distilled water (10g/1) at ambient temperature for 6Q seconds and thoroughly rinsed with water.

As an alternative, a polyester film may be used as the support and prepared using standard procedures.

### Step 2,: Prelaration of first oleophilic formulation

This comprises a solution of BKR2620 thermosetting phenolic resin (resole) (15 wt%) dissolved in.. Dowanol PM (85 wt%).

### Step 3 : Preparation of first ablatable formulation Nitrocellulose DHX 30/50 (25 wt%) and a first solvent mixture (75 wt%) comprising n-butylacetate (10 wt%) and methylethylketone (90 wt%) were mixed and barrel rolled for 24 hours to give formulation A.

Dispercel Tint Black STB-E (12 wt%) and a solvent mixture (88 wt%) comprising n-butylacetate (10 wt%) and methylethylketone (90 wt%) were mixed and barrel rolled for 24 hours to give formulation B.

Formulation A (16.5 wt%), formulation B (67.5 wt%) and a further amount of the first solvent mixture (16.0 wt%) were mixed and barrel rolled for 24 hours to yield the first ablatable formulation.

### Step 4 : Preparation of elate

The oleophilic formulation of Step 2 was coated onto the support of Step 1 to give a dry film weight of 3-7 gm2 after drying at 170° C. for 10 minutes.

Next, the ablatable formulation of Step 3 was coated over the oleophilic formulation to give a film weight of 2-3 gm2 after drying at 100° C. for 60 seconds.

Then PES613D was coated over the ablatable formulation to give a hydrophilic layer having a film weight of 4-6 gm2 after drying at 100° C. for 3 minutes.

### EXAMPLE 2 and 3

The procedure of Example 1 was followed except that PES613D was replaced with WAC-10 and WAC-20 respectively to give negative working ablatable printing plates.

### EXAMPLE 4

Preparation of positive working ablatable printing plate A lithographic printing plate was prepared having the construction shown in FIG. 2 namely a support 2, hydrophilic layer 8, ablatable layer 6 and oleophilic layer 4.

### Step 1 : Preparation of support

This was prepared as in Example 1, Step 1.

### Step 2 : Preparation of second oleophilic formulation

This comprises a solution of BKR2620 (15 wt%) dissolved in n-butanol (85 wt%).

### Step 3 : Preparation of second ablatable formulation

This was prepared as described in Example 1, Step 3, except that n-butylacetate was used instead of the first solvent mixture.

### Step 4 : Preparation of plate

PES613D was coated over the support 2 using a Meyer bar to give a hydrophilic layer having a film weight of 4-12 gm 2 after drying at 100° C. for 3 minutes.

Next, the second ablatable formulation was coated over the hydrophilic layer to give a film weight of 2-3 gm⁻² after drying at 100° C. for 60 seconds.

Then, the second oleophilic formulation was coated over the ablatable formulation to give a film weight 2.5-3.5 gm² after drying at 110° C. for 3 minutes.

### Examples 5 and 6

The procedure of Example 4 was followed except that IPES613D was replaced with WAC-10 and WAC-20 respectively to give positive working ablatable printing plates.

### EXAMPLE 7

Preparation of negative-working ablatable printing Plate Lithographic plates were prepared having the construction shown in FIG. 3 namely an oleophilic support 2, a metal film layer 10 and a hydrophilic layer 8.

In the preparation, polyester film was sputter coated with either platinum or gold using a Fisons Instrument Model SC510 SEM coating system. An argon plasma atmosphere at 10 Pa-pressure with a 20 mA plasma current was used. In-separate examples, two film weights were applied by sputtering for 3 minutes and 12 minutes. A layer of PES613D was applied over the metal layer to give a dry film weight of 4-6 gm2.

### EXAMPLE 8

### Preparation of plate having rubber radiation sensitive laver

A plate was prepared comprising, in order, a support, a hydrophilic layer and a radiation sensitive layer which is arranged so that non-exposed areas can be removed by application of a force, for example by rubbing.

### Step 1 : Preparation of support

This was prepared as in Example 1, Step 1.

### Step 2 : Preparation of radiation sensitive formulation

A first solution of a styrene-butadiene-styrene (SBS) copolymer was prepared by barrel rolling Finaprene 411 (15 wt%) and cyclohexane (85 wt%) for 24 hours.

A second solution comprising styrene-butadiene (SBR) was prepared by ball milling the following for 5 days in a 500 ml porcelain ball mill using porcelain balls to give a final particle size of less than 6pm:Finaprene 1205 (13.59 wt%), Robac TMTD PM (0.15 wt%), sulphur (0.34 wt%). zinc oxide (0.68 wt%), stearic acid (0.14 wt%), carbon black FW2 (6.12 wt%), cyclohexane (59.68 wt%) and SBP3 hydrocarbon (19.30 wt%).

A radiation sensitive formulation was prepared by barrel rolling said first solution (85 wt%) and said second solution (15 wt%).

### Step 3 : PreTaration of plate

PES 613D was coated over the support of Step 1 and dried at 100° C. for 2 minutes to give a hydrophilic layer having a dry film weight of 4-6 gm².

Next, the radiation sensitive formulation of Step 2 was coated over the hydrophilic layer, followed by drying at 80° C. for 1 minute, to give a dry film weight of 1.7-2.1 gm−2.

### EXAMPLE 9

The procedure of Example 8 was followed except that the radiation sensitive formulation was prepared by barrel rolling the first solution (59.15 wt%) and second solution (10.45 wt%) of Step 2 with cyclohexane (29.80 wt%) and Si69 bonding additive (0.60 wt%).

### EXAMPLE 10

### Preparation of first direct phase change (DPC) printina plate

The following direct phase change plate includes an imageable layer which is transformed from being hydrophilic to oleophilic on imagewise exposure to radiation—that is, the plate does not need to be developed or further processed after exposure.

A first DPC formulation was prepared by mixing PES613D (70.00 wt%), ST84 dye (0.12 wt%) and a solvent blend (28.8 wt%) comprising water (75 wt%) and tetrahydrofuran (25 wt%). The formulation was coated onto an aluminium substrate to give a dry film weight of 1.5-2.0 gm² after oven drying at 80° C. for 2 minutes.

### EXAMPLE 11

### Preparation of second DPC Printing Plate

A first component was prepared by mixing and barrel rolling PES 613D (94.7 wt%) and Bayhydur TPLS 2032 (5.3 wt%) for 1 hour.

A second component was prepared by mixing by barrel rolling for 1 hour the first component (78.0 wt%) with SMA 17352 (2.2 wt%) and a solvent blend (19.8 %) comprising water (75 wt%) and tetrahydrofuran (25 wt%). The final formulation was prepared by mixing the second component (70.0 wt%) with ST84 dye (0.12 wt%) and with a solvent blend (28.8 wt%) comprising water (75 wt%) and tetrahydrofuran (25 wt%). The formulation was coated onto an aluminium substrate as for Example 10.

### EXAMPLE 12

### Preparation of positive-workina conventional Plate

### Step 1 Preparation of support

An aluminium support was conventionally cleaned, grained and anodized.

### Step 2 : Preparation of coating formulation

The formulation was prepared by barrel rolling for 60 minutes PES613D (71.5 wt%), Beetle resin BE3717 (6.8 wt%) and water (21.7 wt%).

### Step 3 : Preparation of plate

The formulation of Step 2 was coated onto the support of Step 1 to give a dry film weight of 6-8 gm⁻² following oven drying at 120° C for 3 minutes.

Then, a standard positive-working light sensitive layer of a type which is applied by Horsell Graphic Industries Limited to light sensitive lithographic printing plates sold by them under the Trade Mark CAPRICORN was applied to give a dry coating weight of 1.5 to 2.5 gm² after oven drying at 100° C. for 3 minutes.

### EXAMPLE 13

A plate was prepared as described in Example 12, except that, Melinex 0 was used instead of aluminium.

### EXAMPLE 14

A plate was prepared as described by Example 12, except that to 61 wt% of the coating formulation of Step 2, was added Hombitan LW (17 wt%), Alumina C₃ powder (17 wt%) and water (5 wt%), and the constituents were barrel rolled until thoroughly mixed.

### EXAMPLE 15

A plate was prepared as described in Example 14, but using Melinex O as described in Example 13.

### EXAMPLE 16

### Preparation of negative-working conventional plate

A plate was prepared as described in Example 12, except that a standard negative-working light sensitive layer of a type which is applied by Horsell Graphic Industries Limited to light sensitive lithographic printing plates sold by them under the Trade Mark SCORPIO was applied to give a dry coating weight of 0.8 to 1.2 gm² after drying in an oven at 100° C. for 60 seconds.

### Examples 17 to 19

Plates were prepared as described in Example 16, using supports as described in Examples 13 to 15.

### EXAMPLE 20

### Preparation of thermally imageable Plate

### Step 1 : Preparation of thermally imageable formulation

A dispersion of carbon black FW2 (5.9 wt%), LB6564 phenol novolak resin (23.5 wt%) and methoxy propanol (70.6 wt%) were milled in a 500 ml ball mill for 24 hours using porcelain balls to produce a first dispersion. Then, the first dispersion (42.9 wt%), LB6564 phenol-novolak resin (7.1 wt%), Monazaline C (1.3 wt%) and methoxy propanol (48.7 wt%) were barrel rolled together for 2 hours.

### Step 2

A plate was prepared as described in Example 12, Step 3, except that the thermally-imageable coating formulation was used.

### EXAMPLE 21

A plate was prepared as described in Example 20, except that the support was Melinex 0 instead of aluminium.

### EXAMPLE 22

A plate was prepared as described in Example 20, except that the thermally imageable coating was applied over a layer prepared as described in Example 14.

### EXAMPLE 23

A plate was prepared as described in Example 20, except that the thermally imageable coating was applied over a layer prepared as described in Example 15.

### EXAMPLE 24

Formulations 1 and 2 were prepared by barrel-rolling the components described in the table below for 24 hours.

| | Formulation | Formulation |
|---|---|---|
| Component | 1 (wt %) | 2 (wt %) |
| PES 613D | 63 | 63 |
| Beetle Resin BE 3717 | 6 | 6 |
| KF 654B PINA | 1.2 | — |
| Methylethyl Ketone | 29.8 | 31 |

Then, formulation 1 was coated onto a standard electrograined and anodized aluminium support and then stoved at 120° C. for 1 minute at 2300 r.p.m in a Mathis oven to give a dry film weight of 3.4 gm². Formulation 2 was then coated over the first layer and stoved at 120° C. for three minutes at 2300 r.p.m. The total dry film weight was 7-8 g

Samples of each plate were subjected to heat delivered from a Weller Soldering iron EC 2100M at 316° C. The speed of movement of the soldering iron over the plate surface is described in the table below. The exposed plate samples were then inked in using Horsell RapidInk. The results were identical for a given condition regardless of composition used.

| Speed of soldering iron | | |
|---|---|---|
| movement over plate | | Simple inkability test |
| surface/cm s⁻¹ | Heat applied to . . . | result |
| 1 | coated face of plate | Coating totally inks |
| | | up in area subject to |
| | | heat. |
| 10 | coated face of plate | Coating totally inks |
| | | up in area subjected to |
| | | heat. |
| 20 | coated face of plate | Coating totally inks |
| | | up in area subjected to |
| | | heat. |
| 50 | coated face of plate | Coating totally inks |
| | | up in area subjected to |
| | | heat. |
| 1 | reverse face of plate, | Coating remains |
| | i.e. direct on the | hydrophilic and does |
| | aluminium support | not ink up. |

Assessment of Plates

Assessment 1 :Imaging using horizontal bed image setter

A plate to be imaged was cut into a sample of not 15 less than 1 cm² in area and placed on a flat metallic bed.

Suspended above the sample was a laser scanning system which directed a focused laser beam over the sample surface by means of XY scanning mirrors (two galvanometer scanning mirrors in orthogonal planes). The included scan angle of this system was 40° capable of scanning at up to 7 rad s1 (or 850 mm s⁻¹ at the focal plane). The image to be exposed could be chosen from any image capable of being converted into vector co-ordinates via a CAD package, this including images raster scanned onto the sample surface. In the present case, plates were imaged with a ring pattern having 1.5 cm outside diameter and 0.5 cm inside diameter. The scan speed and dwell time of the laser were selectable-by the operator using the scanner's control software in order to obtain various imaging energy densities.

The laser used was a single mode 830 nm wavelength 200 mW laser diode which was collimated and then focused, after reflection by the XY scanning mirrors, to do a 10 micron spot at the 1/e² points. The laser power supply was a stabilised constant current source.

Assessment 2 : Imaging using rotatable disc apparatus

A plate was cut into a disc of 105 mm diameter and placed on a rotatable disc, that could be rotated at a constant speed of either 100 or 2500 revolutions per minute. Adjacent to the rotatable disc, a translating table held a laser beam source so that it impinged normal to the disc (at 100 to 500 mJ cm⁻¹) while the translating table moved the laser beam radially in a linear fashion with respect-to the rotatable disc. The exposed image was in the form of a spiral whereby the image in the centre of the spiral represented slow laser scanning speed and long exposure time and the outer edge of the spiral represented fast scanning speed and short exposure time.

The laser used was a single mode 830 nm wavelength 200mW laser diode which was focused to a 10 micron spot.

The laser power supply was a stabilised constant current source.

Assessment 3 : Imaging using Creo Trendsetter

A-plate to be imaged was cut into a strip no smaller than 460×300 mm and imaged on a Creo Trendsetter 3244 using Procomm Plus software. The device uses an operating wavelength of 830 nm at powers up to 8 W.

Assessment 4

A plate was exposed on a Montakop UV light frame at 100 units (Examples 12 to 15) or 190 units (Examples 16 to 19) and 20:20 vacuum with a mask and developed for 60 seconds (Examples 12 to 15) or 120 seconds (Examples 16 to 19) with a developer comprising a sodium metasilicate pentahydrate (7 wt%) in water.

Assessment 5 : Inking Test

0.6 to 0.7 g of conventional air drying offset lithographic printing ink was applied to an area of glass plate 15 cm×20-cm in size. This was rolled into a uniform film using a rubber roller.

A plate to-be inked was rinsed in alcohol containing fountain solution and wiped using cotton wool to remove any debris. Awthin film of fountain solution was left on the plate. The plate was then inked using several passes from the inked roller. The plate was then rinsed in water to remove excess ink.

Offset prints were taken by applying the inked face of the plate to a compressible lithographic blanket and rolling over with the roller. The plate was then removed and a piece of paper put in its place. The image was then transferred onto the paper by rolling over with the rubber roller.

The test was a success if a copy of the image originally on the plate was present on the paper. Results

Examples 1 to 6—On imaging using an infra red 830 nm laser, the ablatable layer 6 was removed in imaged areas, taking the layer above (8 or 4) with it, thereby to expose the oleophilic or hydrophilic layers (4 or 8). In Assessment 1, it was found for each Example that plates could be imaged at energy densities down to 300 to 400 mJ cm². In Assessment 2, it was found for each example that the spiral was visible up to the edge of the disc (ie. at 10cm diameter). In Assessment 3, the plates were successfully imaged at 8 W, 41 r.p.m. and 500 mJ cmr² with a text image. In all of the above assessments image areas could be clearly distinguished due to a reduction in gloss. In addition, all of the plates prepared were found to be capable of being used in offset printing when assessed as described in Assessment 4.

Example 7—On imaging as described in Assessment 1 (imaging energy densities down to 300 to 400 mJ cm¹) it was found that the thin metal film layer 10 was disrupted in imaged areas so that it was removed together with layer 8, to expose the polyester support which is ink receptive, whereas the remaining non-imaged area will not. accept ink when wet.

Examples 8 and 9.—The plates imaged at 400 to 500 mj cm² using the apparatus described in Assessment 2 gave an imaged spiral of about 4cm diameter for both examples. The plates were then rubbed by hand in the presence of water and the background checked for the presence of debris and ink receptivity. It was found that the hydrophilic layer visible in exposed areas had a clear background and did not retain ink, whereas non-exposed areas of the radiation sensitive layer did.

Examples 10 and 11—On imaging at 400 to 500 mJ cm² as described in Assessment 2, a colour change could be seen in imaged areas. When the plates were inked as described in Assessment 4,, imaged areas -were found to be ink receptive, whereas non-imaged areas were not.

Examples 12 to 19—These were found to be imageable and developable in Assessment 4 to leave an exposed hydrophilic layer (containing PES 613D) which was non-ink accepting. Accordingly, the plate could be used in printing..

Examples 20 to 23—These were found to be imageable such that areas of the image layer could be selectively removed, leaving an exposed hydrophilic layer (containing PES 613D) which was non-ink accepting. Accordingly, the plate could be used in printing.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A method of preparing a printing member or a printing member precursor, the method comprising contacting a substrate with an aqueous formulation comprising a polyester having pendent hydrophilic groups, wherein said polyester has optionally been combined with a second compound.

2. A method according to claim 1, wherein said formulation and/or said polyester is/are arranged to define a hydrophilic layer.

3. A method according to claim 1 or claim 2, wherein said hydrophilic groups are selected from alkylene oxide moieties, carboxyl groups, amino groups, sulphonic groups, phosphoric groups, sulphuric acid ester salts, hydroxyl groups, salts of any other aforesaid and quaternary ammonium salts in general.

4. A method according to any preceeding claim, wherein said polyester has pendent sulphonic groups.

5. A method according to any preceding claim, wherein the ratio of the number of moles of pendent hydrophilic groups to ester linkages in said polyester is at least 0.05 and less than 0.5.

6. A method according to any preceding claim, wherein said formulation contacted with said substrate in the method includes less than 50 wt% organic solvent.

7. A method according to any preceding claim, wherein said polyester includes a first repeat unit which is an aromatic repeat unit.

8. A method according to any preceding claim, wherein said polyester includes a first repeat unit derivable or derived from terephthalic acid or isophthalic acid.

9. A method according to any preceding claim, wherein said polyester includes a second repeat unit derived or derivable from a compound having at least two hydroxy groups.

10. A method according to any preceding claim, wherein said polyester includes a third repeat unit which includes a said pendent hydrophilic group and which includes an aromatic repeat unit.

11. A method according to any preceding claim, wherein said formulation includes particulate material.

12. A method according to any preceding claim, wherein a printing member prepared is arranged such that after exposure and optional development at least part of an uppermost surface of the member comprises a hydrophilic layer formed by application of said formulation.

13. A method according to any preceding claim, wherein said substrate contacted in the method comprises a support with an oleophilic layer over said support.

14. A method according to claim 13, wherein an ablatable layer is provided over said oleophilic layer.

15. A method according to any of claims 1 to 12, wherein said substrate contacted in the method comprises a support and said formulation is contacted directly with said support.

16. A method according to claim 15, wherein a radiation sensitive layer adapted so that non-exposed areas may be removed by application of a force in a substantially dry process may be applied over said substrate.

17. A method according to any of claims 1 to 12, wherein said substrate comprises a said support and an ablatable layer over said support.

18. A method according to any of claims 1 to 12, wherein said substrate contacted in the method comprises a support provided with a hydrophilic layer.

19. A method according to any of claims 1 to 12, wherein said formulation is, itself, arranged to define an image layer.

20. A method according to claim 19, wherein said aqueous dispersion has been combined with a second compound.

21. A method according to claim 19 or claim 20, wherein said formulation includes a radiation absorber for converting radiation into heat.

22. A method according to any of claims 19 to 21, wherein said formulation includes a dye.

23. A method according to any of claims 19 to 22, wherein said formulation is arranged to be converted from being hydrophilic to oleophilic on exposure to radiation.

24. A printing member or printing member precursor comprising a substrate provided with a first hydrophilic layer prepared or preparable by removing water from an aqueous formulation comprising a polyester having pendent hydrophilic groups, wherein said polyester has optionally been combined with a second compound.

25. A printing member or printing member precursor comprising a substrate provided with a first hydrophilic layer which includes a polyester having pendent hydrophilic groups.

26. A method or a printing member, each being independently as hereinbefore described with reference to the examples.
